(19) United States
(12) Patent Application Publication
(10) Pub. No.: US 2019/0258019 A1
(43) Pub. Date: Aug. 22, 2019

(54) OPTICAL APPARATUS AND CAMERA MODULE

(71) Applicant: SHARP KABUSHIKI KAISHA, Sakai City, Osaka (JP)

(72) Inventors: YOSHIKAZU OHARA, Sakai City (JP); SHOHGO HIROOKA, Sakai City (JP)

(21) Appl. No.: 16/333,480

(22) PCT Filed: May 17, 2017
(86) PCT No.: PCT/JP2017/018442

§ 371 Date: Mar. 14, 2019

(30) Foreign Application Priority Data
Sep. 28, 2016 (JP) 2016-190354

(51) Int. Cl. G02B 7/02; H01L 31/0232; H01L 27/146

(52) U.S. Cl. CPC G02B 7/021; H01L 27/14627; H01L 31/02327

(57) ABSTRACT

[Object] To enable an LOC to have both a reduced size and high design flexibility.

[Solution] A substrate (1) in which an opening (4) is formed, a sensor (2), and a lens (3) are included. The lens (3) has a wiring pattern (5) for electrically connecting the substrate (1) and the sensor (2) to each other.

### TECHNICAL FIELD

The present invention relates to an optical apparatus and a camera module.

### BACKGROUND ART

Relating to an LOC (lens on chip), in which a lens is mounted on a chip, a technology of forming an opening, to reduce the size of an optical apparatus that includes a substrate, a sensor (light-receiving element), and a lens (optical component), in the substrate and disposing the sensor in the opening is proposed (refer to PTL 1 and PTL 2).

### CITATION LIST

### Patent Literature

PTL 1: International Publication No. 2015-151697 (published on Oct. 8, 2015)

PTL 2: International Publication No. 2016-117250 (published on Jul. 28, 2016)

### SUMMARY OF INVENTION

### Technical Problem

In the aforementioned technology, a projection that extends from an inner wall of the opening to above the sensor in a lateral direction is provided, and the projection and the sensor are joined to each other in a vertical direction. Thus, the size of the opening becomes smaller above the sensor. Meanwhile, assuring the size of the opening above the sensor requires an increase in the size of the opening at the sensor and at a portion where the sensor is disposed. Consequently, the aforementioned technology has a problem in which an increase in the cross-sectional area of the substrate, a size increase in the sensor, a decrease in design flexibility resulting from a decrease in the area of the front and rear surfaces of the substrate, an increase in the size (total optical length) of the optical apparatus in the vertical direction, and the like may be caused.

The present invention is made in consideration of the aforementioned problem. An object of the present invention is to provide an optical apparatus and a camera module that enable an LOC both to have a reduced size and to maintain high design flexibility.

### Solution to Problem

To solve the aforementioned problem, an optical apparatus according to one aspect of the present invention includes a substrate in which an opening is formed, a light-receiving element that has a light-receiving portion and that is disposed in the opening, and an optical component that is disposed on an object side with respect to the light-receiving element so as to close the opening and that guides light to the light-receiving portion, the optical component having a wiring pattern for electrically connecting the substrate and the light-receiving element to each other.

In addition, to solve the aforementioned problem, a camera module according to one aspect of the present invention includes the optical apparatus according to the one aspect of the present invention.

### Advantageous Effects of Invention

According to one aspect of the present invention, an LOC is enabled both to have a reduced size and to maintain high design flexibility.

### BRIEF DESCRIPTION OF DRAWINGS

FIG. 1 is a sectional view illustrating a configuration of an optical apparatus according to a first embodiment of the present invention.

FIG. 2 is a sectional view illustrating a configuration of an optical apparatus according to a second embodiment of the present invention.

FIG. 3 is a sectional view illustrating a configuration of an optical apparatus according to a third embodiment of the present invention.

FIG. 4 is a sectional view illustrating a configuration of an optical apparatus according to a fourth embodiment of the present invention.

FIG. 5 is a sectional view illustrating a configuration of an optical apparatus according to a fifth embodiment of the present invention.

FIG. 6 is a sectional view illustrating a configuration of an optical apparatus according to a sixth embodiment of the present invention.

FIG. 7 is a sectional view illustrating a configuration of an optical apparatus according to a seventh embodiment of the present invention.

FIG. 8 is a sectional view illustrating a configuration of an optical apparatus according to an eighth embodiment of the present invention.

FIG. 9 is a sectional view illustrating a configuration of an optical apparatus according to a ninth embodiment of the present invention.

FIG. 10 is a sectional view illustrating a configuration of an optical apparatus according to a tenth embodiment of the present invention.

FIG. 11 is a sectional view illustrating a configuration of an optical apparatus according to an eleventh embodiment of the present invention.

FIG. 12 is a sectional view illustrating a configuration of an optical apparatus according to a twelfth embodiment of the present invention.

FIG. 13(a) is a plan view illustrating a formation example of grooves and a slit with respect to an optical component, and FIG. 13(b) is a sectional view taken along line A-A in FIG. 13(a) as viewed in a direction of the arrows.

FIG. 14 is a plan view illustrating a first modification of an optical component.

FIG. 15(a) is a sectional view illustrating a second modification of an optical component, and FIG. 15(b) is a sectional view illustrating a third modification of an optical component.

### DESCRIPTION OF EMBODIMENTS

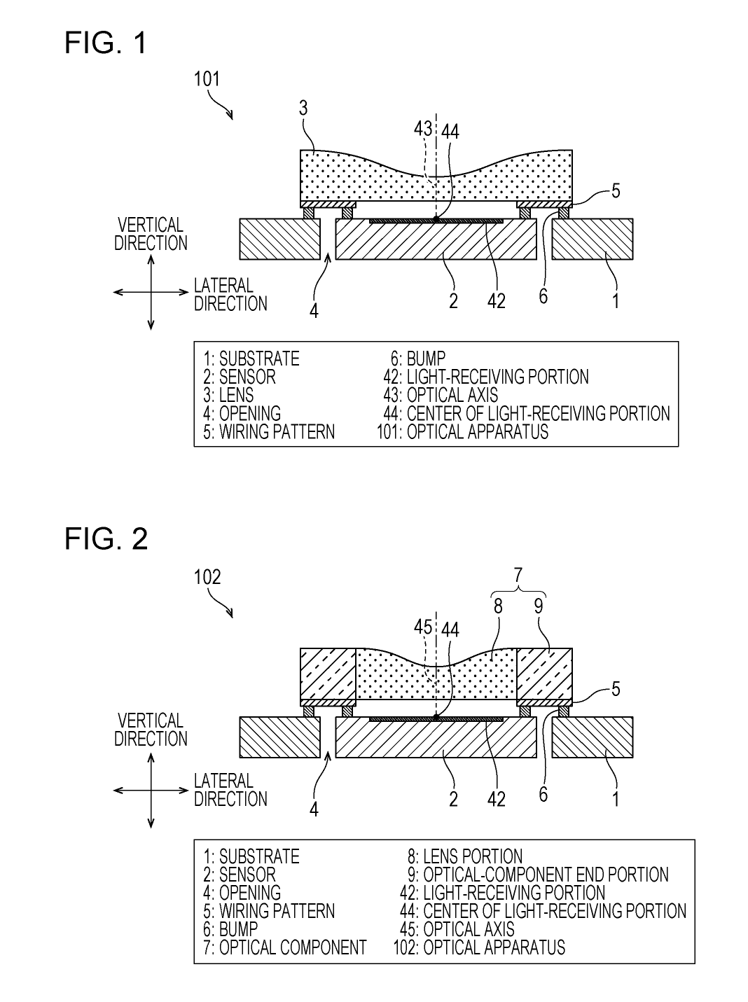

Forms to embody the present invention will be described with reference to FIG. 1 to FIG. 15. Note that, for convenience of description, a member that has a function identical to that of a previously described member is given a reference sign identical to that of the previously described member and will not be described. In the description of the present application, a vertical direction and a lateral direction are defined. The vertical direction extends along an optical axis of an optical apparatus and corresponds to a height direction of the optical apparatus. The lateral direction is a direction orthogonal to the vertical direction and corresponds to a width direction of the optical apparatus. In addition, in the description of the present application, the object side of an optical apparatus is considered the upper side, and the image surface side (sensor side) of the optical apparatus is considered the lower side.

### First Embodiment

FIG. 1 is a sectional view illustrating a configuration of an optical apparatus 101 according to a first embodiment of the present invention. The optical apparatus 101 includes a substrate 1, a sensor 2 (light-receiving element), and a lens 3 (optical component).

The substrate 1 is constituted by, for example, a ceramic, a glass epoxy, or a fiber-reinforced resin (containing, for example, carbon). The substrate 1 is commonly known as a circuit board, on which wiring (not illustrated) is formed. In addition, an opening 4 is formed in the substrate 1. The opening 4 is formed so as to extend through the substrate 1.

The sensor 2 is constituted by, for example, a CCD (charge coupled device) or a CMOS (complementary metal oxide semiconductor). The sensor 2 is disposed in the opening 4. In other words, the sensor 2 is a structure that is accommodated in the substrate 1. The sensor 2 is disposed so as to be adjacent to an inner wall of the opening 4 in the lateral direction. In addition, the sensor 2 has a light-receiving portion 42 on an upper surface (in other words, a surface on the object side) thereof.

The lens 3 is constituted by, for example, a plastic or a glass. The lens 3 is disposed on the object side with respect to the sensor 2 so as to close the opening 4. The lens 3 is disposed for the purpose of guiding light to the light-receiving portion 42. Referring to FIG. 1, the lens 3 has a concave aspherical surface on the object side and has a flat surface or a substantially flat surface on the side (image surface side) of the sensor 2. Note that the shapes of the two surfaces of the lens 3 are not limited thereto. For example, the lens 3 may have an aspherical surface on the side of the sensor 2. In addition, as an alternative to the lens 3, an optical component that converges light with respect to the light-receiving portion 42 while reflecting the light may be used.

The lens 3 has a wiring pattern 5. An example of a technique to form the wiring pattern 5 on the lens 3 is a technique of forming wiring that is constituted by a conductor made of copper or the like on the lens 3 by a known method such as a sputtering method or an etching method. In a glass substrate, an oxide thin film having excellent conductivity may be formed as the wiring pattern 5 by a dry method such as CVD (chemical vapor deposition) or a magnetron sputtering method or by a wet method such as a sol-gel method or a spray pyrolysis method. Plating may be further formed on the thin-film wiring to obtain the wiring pattern 5. The wiring pattern 5 is formed on a surface of the lens 3 on the side of the sensor 2. The wiring pattern 5 is for electrically connecting the substrate 1 and the sensor 2 to each other.

A surface of the substrate 1 on the side of the lens 3 and the wiring pattern 5 are joined and electrically connected to each other by a bump 6 for flip-chip connection while a surface of the sensor 2 on the side of the lens 3 and the wiring pattern 5 are joined and electrically connected to each other by the bump 6. Consequently, the substrate 1 and the sensor 2 are electrically connected to each other via the wiring pattern 5. The bump 6 used to join and electrically connect the surface of the substrate 1 on the side of the lens 3 and the wiring pattern 5 to each other may be previously formed on either one of the wiring pattern 5 provided on the lens 3 and the wiring provided on the substrate 1. As an alternative to the bump 6, an anisotropic conductive material such as an ACF (anisotropic conductive film) or an ACP (anisotropic conductive paste) may be used.

According to the optical apparatus 101, it is not required to increase the size of the opening 4 at the sensor 2 and at a portion where the sensor 2 is disposed because the size of the opening 4 is prevented from becoming smaller above the sensor 2 as a result of a projection that extends from the inner wall of the opening 4 in the lateral direction being not required. Consequently, it is possible to prevent an increase in the cross-sectional area of the substrate 1, a size increase in the sensor 2, a decrease in design flexibility resulting from a decrease in the area of the front and rear surfaces of the substrate 1, an increase in the size (total optical length) of the optical apparatus in the vertical direction, and the like. Therefore, according to the optical apparatus 101, an LOC is enabled both to have a reduced size and to maintain high design flexibility.

Here, when the lens 3 inclines with respect to the light-receiving portion 42 in the optical apparatus 101, there is a chance that a partial blur failure occurs or a failure in the electrical connection between the substrate 1 and the sensor 2 occurs. Thus, in the optical apparatus 101, it is preferable that the surface of the sensor 2 on the side of the lens 3 and the lens 3 be separated from each other by a predetermined distance (for example, 10 μm or more) due to the thickness of the bump 6 and that an optical axis 43 of the lens 3 and a center 44 of the light-receiving portion 42 be aligned with each other.

### Second Embodiment

FIG. 2 is a sectional view illustrating a configuration of an optical apparatus 102 according to a second embodiment of the present invention. The configuration of the optical apparatus 102 differs from the configuration of the optical apparatus 101 (refer to FIG. 1) in terms of an optical component 7 being included as an alternative to the lens 3.

The optical component 7 is disposed on the object side with respect to the sensor 2 so as to close the opening 4. The optical component 7 has a lens portion 8 and an optical-component end portion 9 (lens-surrounding portion).

The lens portion 8 is constituted by, for example, a plastic or a glass. The lens portion 8 is provided for the purpose of guiding light to the light-receiving portion 42. Referring to FIG. 2, the lens portion 8 has a concave aspherical surface on the object side and has a flat surface or a substantially flat surface on the side (image surface side) of the sensor 2. The shapes of the two surfaces of the lens portion 8 may have variations equivalent to the shapes of the two surfaces of the lens 3.

The optical-component end portion 9 is constituted by, for example, a ceramic, a glass epoxy, a fiber-reinforced resin, a plastic such as a reinforced heat-resistant plastic, a glass, a metal, or a glass epoxy. The optical-component end portion 9 is a hollow member that is disposed around the lens portion 8.

In the optical apparatus 102, the wiring pattern 5 is formed on the optical-component end portion 9, more specifically, on a surface of the optical-component end portion 9 on the side of the sensor 2. Note that the wiring pattern 5 may be formed on the lens portion 8, more specifically, on a surface of the lens portion 8 on the side of the sensor 2.

When the substrate 1 and the wiring pattern 5 are joined to each other by using the bump 6 or an anisotropic conductive material and when the sensor 2 and the wiring pattern 5 are joined to each other by using the bump 6 or an anisotropic conductive material, pressurizing and heating are required. It is possible to prevent the optical characteristics of the optical component 7 from being changed due to the pressurizing and heating by providing the optical-component end portion 9 around the lens portion 8 while employing as the optical-component end portion 9 a member that has high resistance to a pressure and excellent heat resistance compared with the lens portion 8.

The shape of each surface of the lens portion 8 is determined in accordance with the shape of the light-receiving portion 42. Typically, the light-receiving portion 42 has a rectangular shape in plan view, and thus, the shape of the surface of the lens portion 8 on the side of the sensor 2 is preferably a rectangular shape in plan view or a substantially rectangular shape in plan view. Note that, when the bump 6 and the light-receiving portion 42 are away from each other by a sufficient distance, the shape of the surface of the lens portion 8 on the side of the sensor 2 may be a circular shape in plan view or an oval shape or the like in plan view. In addition, the shape of a surface of the lens portion 8 on the object side is only required to be a shape that does not degrade the performance of the optical apparatus 102, for example, by blocking light and may be a rectangular shape in plan view, a circular shape in plan view, or an oval shape or the like in plan view.

It is possible to create the optical component 7 by setting the optical-component end portion 9 in a molding die and forming the lens portion 8 so as to be integral with the optical-component end portion 9 through injection molding. Consequently, the optical-component end portion 9 and an optical axis 45 of the lens portion 8 are integral with each other, and thus, it becomes easy to align the center 44 of the light-receiving portion 42 and the optical axis 45 with each other.

With the lens portion 8 in plan view, the area of the surface of the lens portion 8 on the object side may be larger than the area of the surface of the lens portion 8 on the side of the sensor 2. A sectional shape of the optical component 7 corresponding to this configuration may be, for example, a funnel shape or a conical shape.

After the optical component 7 is created, a perpendicular direction with respect to the surface of the optical-component end portion 9 on the side of the sensor 2 and the direction of the optical axis 45 are made to coincide with each other. Consequently, it becomes possible to make the optical axis 45 perpendicular to a reference, the reference being the surface of the optical-component end portion 9 on the side of the sensor 2.

When the direction perpendicular to the surface of the optical-component end portion 9 on the side of the sensor 2 and the direction in which the optical axis 45 extends coincide with each other and when the surface of the lens portion 8 on the side of the sensor 2 is flush with the surface of the optical-component end portion 9 on the side of the sensor 2 or positioned closer than the surface of the optical-component end portion 9 on the side of the sensor 2 to the object side, it is possible to prevent contact between the lens portion 8 and the light-receiving portion 42, even when a clearance between the optical-component end portion 9 and the sensor 2 is small. Thus, it is possible to prevent occurrence of an abnormality and the like in an image displayed by the sensor 2.

### Third Embodiment

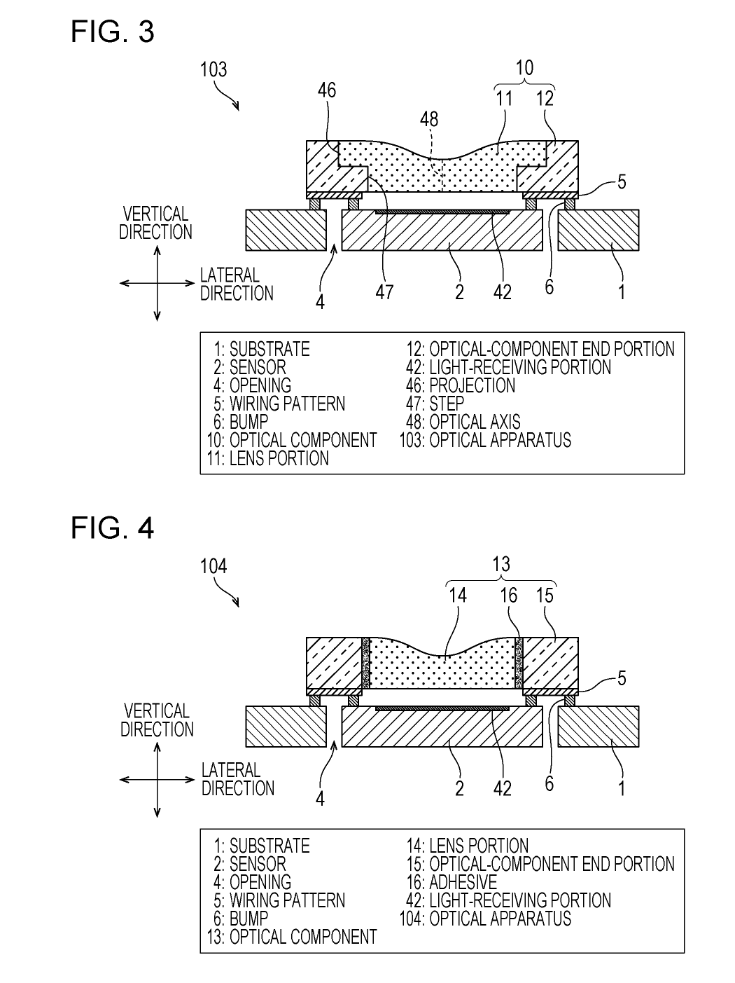

FIG. 3 is a sectional view illustrating a configuration of an optical apparatus 103 according to a third embodiment of the present invention. The configuration of the optical apparatus 103 differs from the configuration of the optical apparatus 102 (refer to FIG. 2) in terms of an optical component 10 being included as an alternative to the optical component 7.

The optical component 10 has a lens portion 11, which corresponds to a configuration in which a projection 46 is formed with respect to the lens portion 8, and an optical-component end portion 12, which corresponds to a configuration in which a step 47 is formed with respect to the optical-component end portion 9. In the optical component 10, the projection 46 is formed on a side surface of the lens portion 11, and the step 47 is formed on an inner wall of the optical-component end portion 12. The projection 46 and the step 47 are in contact with each other in a direction parallel to an optical axis 48 of the lens portion 11 (that is, in the vertical direction).

According to the optical apparatus 103, it is possible to easily align the lens portion 11 and the optical-component end portion 12 with each other. Specifically, in the optical apparatus 103, the projection 46 and the step 47 engage each other, and this engagement improves accuracy in assembling the optical component 10.

The shape of a surface of the lens portion 11 on the side of the sensor 2 may be a rectangular shape in plan view (a shape corresponding to the shape of the light-receiving portion 42 in plan view), and the shape of the lens portion 11 on the object side may be a substantially rectangular shape in plan view or a substantially circular shape in plan view. Consequently, it is possible to make the shape of the projection 46 and the step 47 sharp. Thus, the mechanical strength of the optical component 10 is easily improved by the aforementioned engagement. In addition, a plurality of the projections 46 and a plurality of the steps 47 that correspond to the projections 46 on a one-to-one basis may be formed.

### Fourth Embodiment

FIG. 4 is a sectional view illustrating a configuration of an optical apparatus 104 according to a fourth embodiment of the present invention. The configuration of the optical apparatus 104 differs from the configuration of the optical apparatus 102 (refer to FIG. 2) in terms of an optical component 13 being included as an alternative to the optical component 7.

The optical component 13 has a lens portion 14, an optical-component end portion 15, and an adhesive 16 (adhesive material). The configuration of the lens portion 14 as a single body is identical to the configuration of the lens portion 8. The configuration of the optical-component end portion 15 as a single body is identical to the configuration of the optical-component end portion 9. However, the configuration of the lens portion 14 and the optical-component end portion 15 differs from the configuration of the lens portion 8 and the optical-component end portion 9 in terms of the lens portion 14 and the optical-component end portion 15 being bonded to each other by the adhesive 16.

As the adhesive 16, for example, an epoxy-based adhesive or an adhesive that has a function of curing when irradiated with ultraviolet rays is usable. In the optical apparatus 104, the adhesive 16 is provided between a side surface of the lens portion 14 and an inner wall of the optical-component end portion 15, and the lens portion 14 and the optical-component end portion 15 are bonded to each other in the lateral direction and in the vertical direction.

According to the optical apparatus 104, it is possible to create the optical component 13 by bonding the lens portion 14 and the optical-component end portion 15, which are members separated from each other, to each other with the adhesive 16.

A surface of the lens portion 14 on the side of the sensor 2 may be positioned closer than a surface of the optical-component end portion 15 on the side of the sensor 2 to the object side. Consequently, it is possible to reduce a chance of the adhesive 16 that has flowed out on the surface of the lens portion 14 on the side of the sensor 2, for example, damaging the light-receiving portion 42.

Preferably, the adhesive 16 has light-blocking properties. Consequently, it is possible to prevent, when the optical-component end portion 15 is a light-transmissive member made of a glass or the like, flare or ghosting from being generated in an image obtained from the sensor 2 as a result of light being reflected inside the lens portion 14. As an alternative to the adhesive 16, a paint that has light-blocking properties may be used as an adhesive material.

Preferably, the adhesive 16 has elasticity. Consequently, it is possible to prevent a malfunction from occurring in the optical apparatus 104 as a result of the optical component 13 being broken when a shock such as vibrations is applied to the optical apparatus 104. Specifically, it is possible to prevent a bulk fracture of each member, an interface fracture between the members, and the like in the optical component 13. Moreover, it is also possible to reduce a chance of occurrence of a partial blur as a result of the optical component 13 inclining, because it is possible to buffer stress that is generated along with expansion and contraction of each member.

### Fifth Embodiment

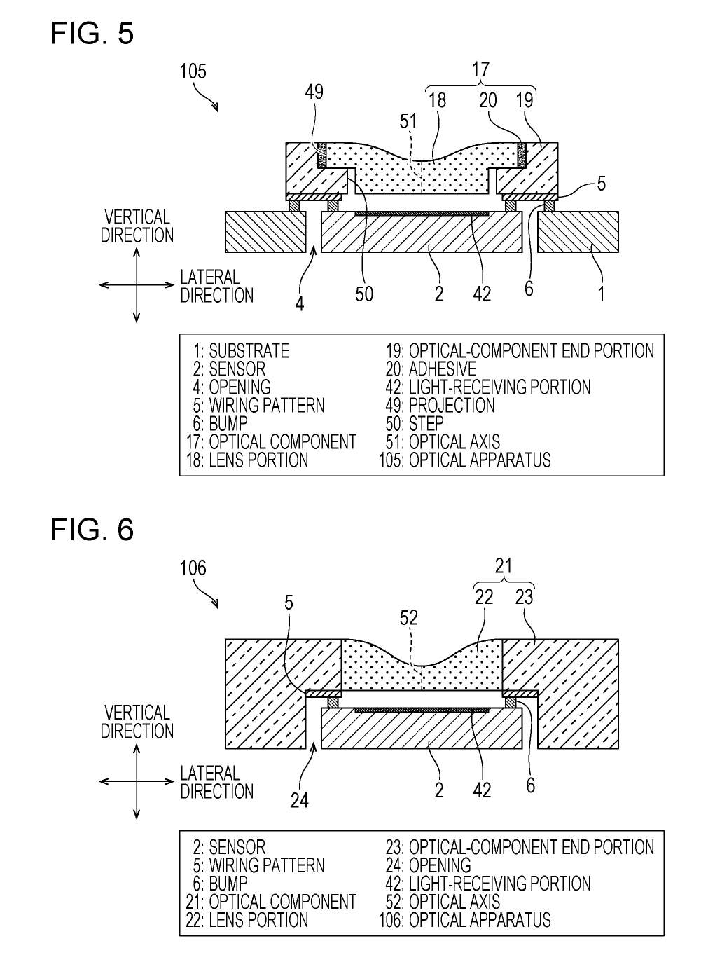

FIG. 5 is a sectional view illustrating a configuration of an optical apparatus 105 according to a fifth embodiment of the present invention. The configuration of the optical apparatus 105 differs from the configuration of the optical apparatus 103 (refer to FIG. 3) in terms of an optical component 17 being included as an alternative to the optical component 10.

The optical component 17 has a lens portion 18, an optical-component end portion 19, and an adhesive 20 (adhesive material). The configuration of the lens portion 18 as a single body is identical to the configuration of the lens portion 11. The configuration of the optical-component end portion 19 as a single body is identical to the configuration of the optical-component end portion 12. However, the configuration of the lens portion 18 and the optical-component end portion 19 differs from the configuration of the lens portion 11 and the optical-component end portion 12 in terms of the lens portion 18 and the optical-component end portion 19 being bonded to each other by the adhesive 20.

As the adhesive 20, for example, an epoxy-based adhesive or an adhesive that has a function of curing when irradiated with ultraviolet rays is usable. In the optical apparatus 105, a projection 49 of the lens portion 18, the projection 49 corresponding to the projection 46 of the lens portion 11, and a step 50 of the optical-component end portion 19, the step 50 corresponding to the step 47 of the optical-component end portion 12 are in contact with each other in a direction parallel to an optical axis 51 of the lens portion 18 (that is, in the vertical direction). The lens portion 18 and the optical-component end portion 19 are bonded to each other by the adhesive 20 at a portion that differs from a portion where the projection 49 and the step 50 are in contact with each other. Specifically, in the optical apparatus 105, the adhesive 20 is provided between a leading end of the projection 49 and an inner wall of the optical-component end portion 19, the inner wall being positioned closer than the step 50 to the object side, and the lens portion 18 and the optical-component end portion 19 are bonded to each other in the lateral direction and in the vertical direction.

According to the optical apparatus 105, it is possible to create the optical component 17 by bonding the lens portion 18 and the optical-component end portion 19, which are members separated from each other, to each other with the adhesive 20. In the optical apparatus 105, the adhesive 20 is provided only in the vicinity of a surface of the lens portion 18 on the object side. Consequently, it is possible to prevent the adhesive 20 from flowing out on the side of the sensor 2 with respect to the optical component 17.

Preferably, the adhesive 20 has light-blocking properties. Consequently, it is possible to prevent, when the optical-component end portion 19 is a light-transmissive member made of a glass or the like, flare or ghosting from being generated in an image obtained from the sensor 2 as a result of light being reflected inside the lens portion 18. As an alternative to the adhesive 20, a paint that has light-blocking properties may be used as an adhesive material.

Preferably, the adhesive 20 has elasticity. Consequently, it is possible to prevent a malfunction from occurring in the optical apparatus 105 as a result of the optical component 17 being broken when a shock such as vibrations is applied to the optical apparatus 105. Moreover, it is also possible to reduce a chance of occurrence of a partial blur as a result of the optical component 17 inclining, because it is possible to buffer stress that is generated along with expansion and contraction of each member.

The adhesive 20 may be provided in the vicinity of a surface of the lens portion 18 on the side of the sensor 2. In addition, the adhesive 20 may be provided both in the vicinity of the surface of the lens portion 18 on the object side and in the vicinity of the surface of the lens portion 18 on the side of the sensor 2.

A plurality of the projections 49 and a plurality of the steps 50 that correspond to the projections 49 on a one-to-one basis may be formed.

### Sixth Embodiment

FIG. 6 is a sectional view illustrating a configuration of an optical apparatus 106 according to a sixth embodiment of the present invention. The optical apparatus 106 includes the sensor 2 and an optical component 21.

The optical component 21 has a lens portion 22 and an optical-component end portion 23. The configuration of the lens portion 22 as a single body is identical to the configuration of the lens portion 8 (refer to FIG. 2).

The optical-component end portion 23 is constituted by, for example, a ceramic, a glass epoxy, a fiber-reinforced resin, or a glass. The optical-component end portion 23 is a hollow member that is disposed around the lens portion 22.

An opening 24 is formed in the optical-component end portion 23. The opening 24 is formed so as to extend through the optical-component end portion 23. The sensor 2 is disposed in the opening 24.

In the optical apparatus 106, the wiring pattern 5 is formed on the optical-component end portion 23, more specifically, on a surface (a surface that faces an upper surface of the sensor 2 in this embodiment) of the optical-component end portion 23 on the side of the sensor 2. However, the wiring pattern 5 may be formed on the lens portion 22, more specifically, on a surface of the lens portion 22 on the side of the sensor 2. A surface of the sensor 2 on the side of the optical component 21 (a surface of the sensor 2 on the object side in this embodiment) and the wiring pattern 5 are joined and electrically connected to each other by the bump 6. Consequently, the sensor 2 and the optical component 21 are electrically connected to each other via the wiring pattern 5.

In other words, the configuration of the optical-component end portion 23 functions as both the configuration of the optical-component end portion 9 (refer to FIG. 2) and the configuration of the substrate 1 (refer to FIG. 1). The optical-component end portion 23 extends in a direction parallel to an optical axis 52 of the lens portion 22 (that is, in the vertical direction) to a location next to the sensor 2.

The optical apparatus 106 is commonly known as a cavity structure, in which at least surfaces, excluding a bottom surface, of the sensor 2 are surrounded by the optical component 21. The cavity structure enables the sensor 2 to be protected by the optical component 21. The effect of the protection of the sensor 2 by the optical component 21 is further improved when the bottom surface of the sensor 2 is also surrounded by the optical component 21, which is not illustrated. A gap between the sensor 2 and the optical-component end portion 23 may be sealed with a resin or the like. Consequently, the effect of protecting the sensor 2 is further improved.

In addition, the rear surface side of the sensor 2 may be also sealed with a resin or the like while the gap between the sensor 2 and the optical-component end portion 23 is sealed with a resin or the like. Consequently, the effect of protecting the sensor 2 is further improved.

### Seventh Embodiment

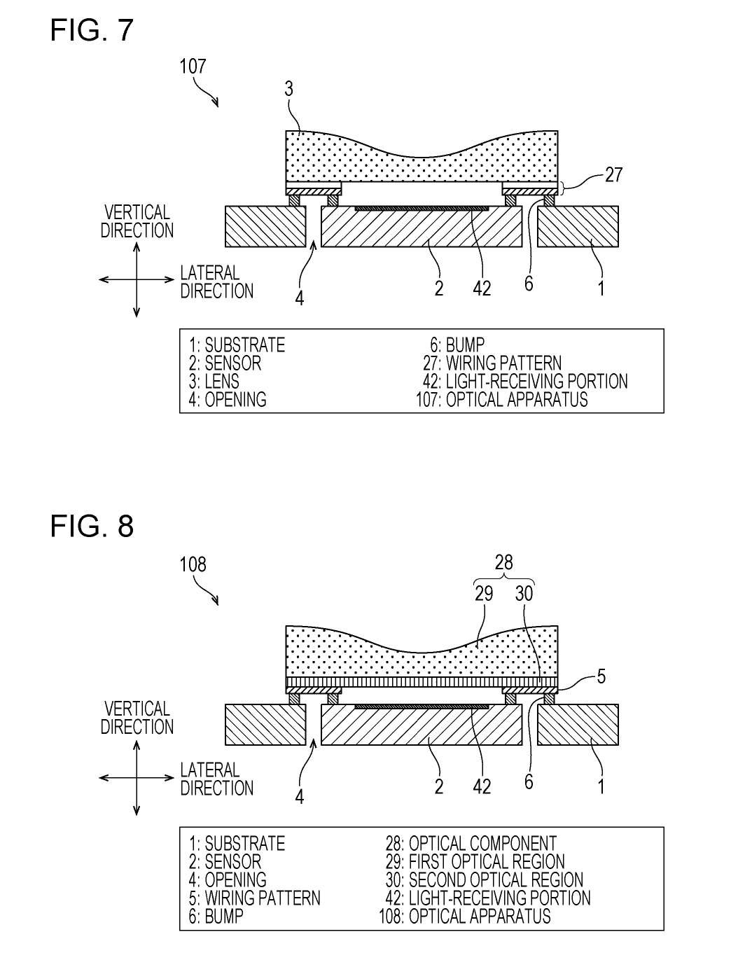

FIG. 7 is a sectional view illustrating a configuration of an optical apparatus 107 according to a seventh embodiment of the present invention. The configuration of the optical apparatus 107 differs from the configuration of the optical apparatus 101 (refer to FIG. 1) in terms of a wiring pattern 27 being included as an alternative to the wiring pattern 5.

The configuration of the wiring pattern 27 differs from the configuration of the wiring pattern 5 in terms of the wiring pattern 27 being constituted by a molded interconnect device (MID). The wiring pattern 27 has light-blocking properties.

An example of a process of forming the wiring pattern 27 on the lens 3 is described below. First, a mask is formed on the lens 3, and a base material of the molded interconnect device is applied on the mask to thereby form a conductive film on the lens 3. Next, the conductive film is etched to thereby form the wiring pattern 27, and then, the mask is removed.

Each of the wiring pattern 5 and the wiring pattern 27 may be formed on a surface (commonly known as a pre-paint surface) of a coating provided on the surface of the lens 3. It is possible to prevent flare or ghosting from being generated in an image obtained from the sensor 2 as a result of light being reflected inside the lens 3, because the surface of the coating has light-blocking properties.

Each of the optical apparatus 102 to the optical apparatus 106 may employ the configuration of the wiring pattern 27 as an alternative to the configuration of the wiring pattern 5. The same applies to an optical apparatus 108 to an optical apparatus 110, which will be described later.

### Eighth Embodiment

FIG. 8 is a sectional view illustrating a configuration of the optical apparatus 108 according to an eighth embodiment of the present invention. The configuration of the optical apparatus 108 differs from the configuration of the optical apparatus 101 (refer to FIG. 1) in terms of an optical component 28 being included as an alternative to the lens 3.

The optical component 28 has a first optical region 29 and a second optical region 30. The first optical region 29 includes a surface of the optical component 28 on the object side and is made of a plastic. The first optical region 29 has a function equivalent to that of the lens 3. The second optical region 30 includes a surface of the optical component 28 on the side of the sensor 2 and is made of a glass. The second optical region 30 is a plate-shaped member that is fixed to a surface of the first optical region 29 on the side of the sensor 2.

Typically, lenses that are represented by lenses for LOC (lens on chip) use have a thickness deviation that increases as the performance of the lenses increases, and the thickness of the lenses is thus required to be reduced, which increases the degree of difficulty in molding. In particular, the degree of difficulty in molding a glass lens is remarkably high compared with that of a plastic lens. The optical component 28 has the second optical region 30 in addition to the first optical region 29, and it is thus possible to form the optical component 28 so as to have a large thickness deviation and so as to be thin compared with the lens 3. In addition, the optical component 28 has the second optical region 30 that is made of a glass and thus has high resistance to a load and excellent heat resistance.

The second optical region 30 may be made of a plastic. In this case, a plastic material of the second optical region 30 preferably has a glass transition temperature Tg and strength that are higher than those of a plastic material of the first optical region 29. In this case, specifically, it is preferable that the plastic material of the first optical region 29 be, for example, polycarbonate (Tg=140° C., load deflection temperature=120 to 140° C., die temperature=100 to 150° C.) and that the plastic material of the second optical region 30 be, for example, polyarylate (Tg=210 to 260° C., load deflection temperature=240 to 250° C., die temperature=140 to 200° C.).

### Ninth Embodiment

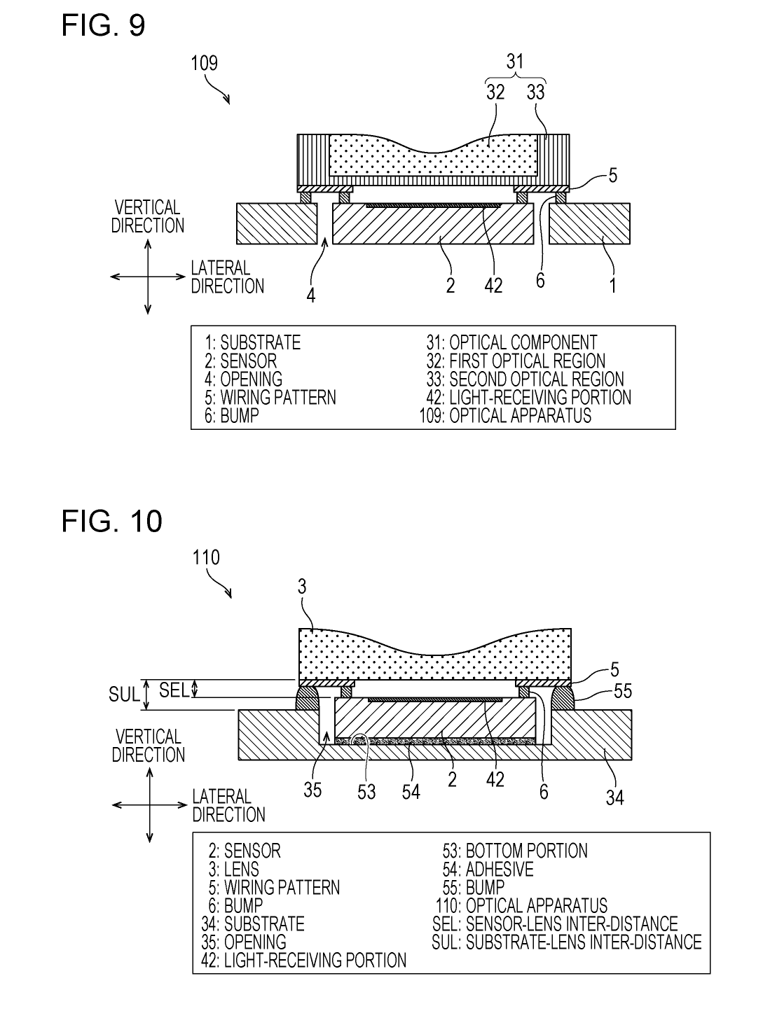

FIG. 9 is a sectional view illustrating a configuration of an optical apparatus 109 according to a ninth embodiment of the present invention. The configuration of the optical apparatus 109 differs from the configuration of the optical apparatus 108 (refer to FIG. 8) in terms of an optical component 31 being included as an alternative to the optical component 28.

The optical component 31 has a first optical region 32 and a second optical region 33. The first optical region 32 includes a surface of the optical component 31 on the object side and is made of a plastic. The first optical region 32 has a configuration similar to the configuration of the first optical region 29 except for a feature of having a size that is slightly small compared with the first optical region 29. The second optical region 33 includes a surface of the optical component 31 on the side of the sensor 2 and is made of a glass. The second optical region 33 is fixed to a surface of the first optical region 32 on the side of the sensor 2. The second optical region 33 extends to a location around (next to) the first optical region 32. The second optical region 33 is fixed to a side surface of the first optical region 32.

The optical apparatus 109 exerts an effect similar to that of the optical apparatus 108 and has a configuration in which the first optical region 32 is protected by the second optical region 33. It is possible to more effectively protect the first optical region 32 when the hardness of the second optical region 33 is higher than the hardness of the first optical region 32.

### Tenth Embodiment

FIG. 10 is a sectional view illustrating a configuration of the optical apparatus 110 according to a tenth embodiment of the present invention. The configuration of the optical apparatus 110 differs from the configuration of the optical apparatus 101 (refer to FIG. 1) in terms of a substrate 34 being included as an alternative to the substrate 1.

The substrate 34 is constituted by a material identical to that of the substrate 1. The substrate 34 is commonly known as a circuit board, on which wiring (not illustrated) is formed. An opening 35 is formed in the substrate 34. The opening 35 is, however, not formed so as to extend through the substrate 34. In other words, a recessed portion that has a bottom portion 53 that closes an end portion of the opening 35 on a side opposite to the lens 3 is formed in the substrate 34. The sensor 2 is disposed at the bottom portion 53 and fixed to the bottom portion 53 by an adhesive 54.

A surface of the substrate 34 on the side of the lens 3 and the wiring pattern 5 are joined and electrically connected to each other by a bump 55 while a surface of the sensor 2 on the side of the lens 3 and the wiring pattern 5 are joined and electrically connected to each other by the bump 6. Consequently, the substrate 34 and the sensor 2 are electrically connected to each other via the wiring pattern 5.

The bump 55 is, for example, a Au (gold) bump. The thickness of the bump 55 is larger than the thickness of the bump 6. A clearance (substrate-lens inter-distance SUL in FIG. 10) between the substrate 34 and the lens 3 is larger than a clearance (sensor-lens inter-distance SEL in FIG. 10) between the sensor 2 and the lens 3. The clearance between the substrate 34 and the lens 3 and the clearance between the sensor 2 and the lens 3 may be equal to each other.

In the optical apparatus 110, the sensor 2 is fixed to the substrate 34. In this case, even when the sensor 2 inclines with respect to the substrate 34, the inclination of the lens 3 with respect to the sensor 2 is not affected. The thickness of the bump 55 is larger than the thickness of the bump 6. Consequently, it is possible to electrically connect the substrate 34 and the wiring pattern 5 to each other reliably even when the clearance between the substrate 34 and the lens 3 is slightly large. As a result, it is possible to provide the highly reliable optical apparatus 110.

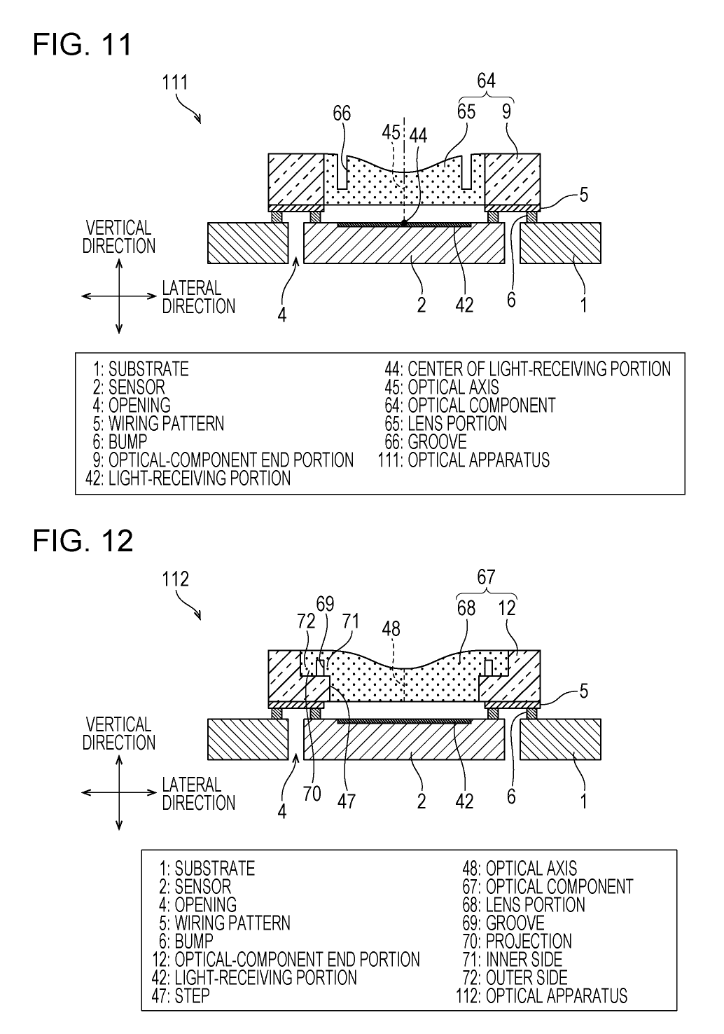

As an alternative to the lens 3, the optical component 7 (refer to FIG. 2), the optical component 10 (refer to FIG. 3), the optical component 13 (refer to FIG. 4), the optical component 17 (refer to FIG. 5), the optical component 28 (refer to FIG. 8), or the optical component 31 (refer to FIG. 9) may be used. In addition, as an alternative to the lens 3, an optical component 64 (refer to FIG. 11) or an optical component 67 (refer to FIG. 12), which will be described later, may be used. Moreover, as an alternative to the wiring pattern 5, the wiring pattern 27 (refer to FIG. 7) may be formed.

Further, in the optical apparatus 110, the substrate 1 may be used as an alternative to the substrate 34.

### Eleventh Embodiment

FIG. 11 is a sectional view illustrating a configuration of an optical apparatus 111 according to an eleventh embodiment of the present invention. The configuration of the optical apparatus 111 differs from the configuration of the optical apparatus 102 (refer to FIG. 2) in terms of the optical component 64 being included as an alternative to the optical component 7. The configuration of the optical component 64 differs from the configuration of the optical component 7 in terms of a lens portion 65 that has a groove 66 being included as an alternative to the lens portion 8.

The groove 66 is formed in a surface of the lens portion 65 on the object side. Compared with the optical apparatus 102, according to the optical apparatus 111, it is possible to prevent, in a procedure similar to that when the adhesive 16 (refer to FIG. 4) has elasticity, a malfunction from occurring in the optical apparatus 111 as a result of the optical component 64 being broken when a shock such as vibrations is applied to the optical apparatus 111. In addition, it is possible to reduce a chance of occurrence of a partial blur as a result of the optical component 64 inclining, because it is possible to buffer, in the procedure similar to that when the adhesive 16 has elasticity, stress that is generated along with expansion and contraction of each member.

The groove 66 may be formed in a surface of the lens portion 65 on the side of the sensor 2 and may be formed in both the surface of the lens portion 65 on the object side and the surface of the lens portion 65 on the side of the sensor 2. The groove 66 may be formed in the lens 3 (refer to FIG. 1), the lens portion 11 (refer to FIG. 3), the lens portion 14 (refer to FIG. 4), the lens portion 18 (refer to FIG. 5), the lens portion 22 (refer to FIG. 6), the first optical region 29 (refer to FIG. 8), or the first optical region 32 (refer to FIG. 9).

### Twelfth Embodiment

FIG. 12 is a sectional view illustrating a configuration of an optical apparatus 112 according to a twelfth embodiment of the present invention. The configuration of the optical apparatus 112 differs from the configuration of the optical apparatus 103 (refer to FIG. 3) in terms of the optical component 67 being included as an alternative to the optical component 10. The configuration of the optical component 67 differs from the configuration of the optical component 10 in terms of a lens portion 68 that has a groove 69 being included as an alternative to the lens portion 11.

The groove 69 is formed in a surface of a projection 70, which corresponds to the projection 46, on the side of the sensor 2. The groove 69 is formed in a location between an inner side 71 of the projection 70 and an outer side 72 of the projection 70. Compared with the optical apparatus 103, according to the optical apparatus 112, it is possible to prevent, in a procedure similar to that when the adhesive 20 (refer to FIG. 5) has elasticity, a malfunction from occurring in the optical apparatus 112 as a result of the optical component 67 being broken when a shock such as vibrations is applied to the optical apparatus 112. Moreover, it is possible to reduce a chance of occurrence of a partial blur as a result of the optical component 67 inclining because it is possible to buffer, in the procedure similar to that when the adhesive 20 has elasticity, stress that is generated along with expansion and contraction of each member. In addition, according to the optical apparatus 112, it is possible to suppress displacement and deformation from occurring in the entire projection 70, even when the outer side 72 is twisted or deformed.

The groove 69 may be formed in a surface of the lens portion 68 on the object side and may be formed in both a surface of the lens portion 68 on the side of the sensor 2 and the surface of the lens portion 68 on the object side. The groove 69 may be formed in the lens 3 (refer to FIG. 1) or on the lens portion 18 (refer to FIG. 5).

### Thirteenth Embodiment

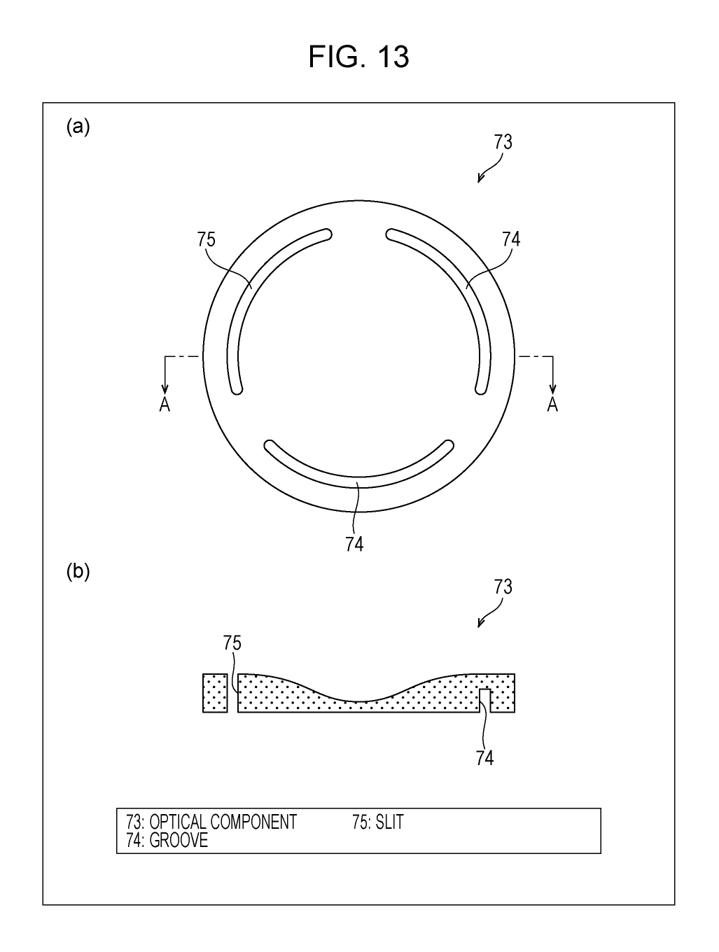

FIG. 13(a) is a plan view illustrating a formation example of grooves and a slit with respect to an optical component. FIG. 13(b) is a sectional view taken along line A-A in FIG. 13(a) as viewed in a direction of the arrows. Specifically, grooves 74 and a slit 75 are formed in one surface of an optical component 73, and the surface of the optical component 73 is illustrated in FIG. 13(a).

The optical component 73 is one of the above-described optical components in which the grooves 74 and the slit 75 are formed. The grooves 74 each correspond to one of the groove 66 (refer to FIG. 11) and the groove 69 (refer to FIG. 12). The shape of the slit 75 differs from the shape of the grooves 74 in terms of the shape of the slit 75 extending through the optical component 73. The slit 75 has a function equivalent to that of the grooves 74.

Only one of the grooves 74 and the slit 75 may be formed in the optical component 73. In the optical component 73, the total number of the grooves 74 and the slit 75 is three but may be two or less or four or more.

### Fourteenth Embodiment

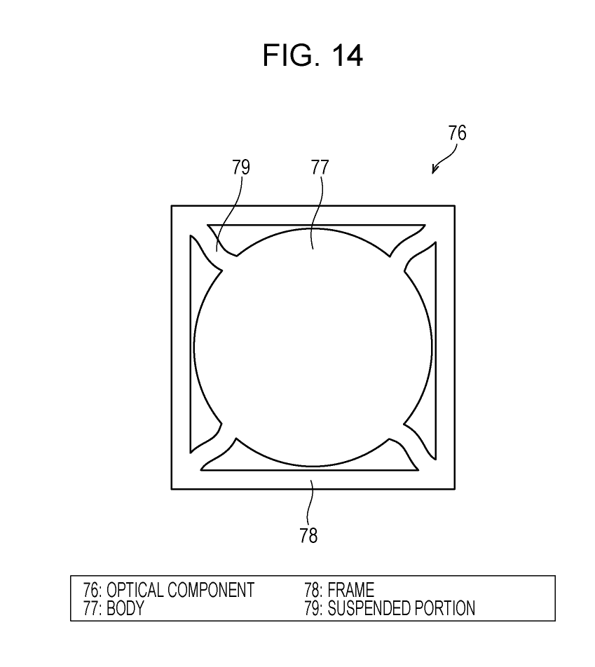

FIG. 14 is a plan view illustrating a first modification of an optical component. An optical component 76 illustrated in FIG. 14 is usable as an alternative to each of the above-described optical components.

The optical component 76 includes a body 77, a frame 78, and four suspended portions 79. The frame 78 has a rectangular shape or a substantially rectangular shape. The four suspended portions 79 are fixed to the four vertexes of the rectangular shape on a one-to-one basis. The body 77 is a portion that functions as a lens that guides light to the light-receiving portion 42 (refer to FIG. 1). The body 77 is fixed to the four suspended portions 79 and is thereby supported by the frame 78. In other words, each of the suspended portions 79 is suspended between the body 77 and the frame 78.

A gap between two mutually-adjacent suspended portions of the four suspended portions 79 corresponds to the slit 75. When the grooves 74 are formed in the optical component 76, the suspended portions 79 may serve as the bottom portions of the grooves 74.

According to the optical component 76, it is possible to achieve a size reduction and high performance in the optical apparatus while suppressing an optically effective region from decreasing.

### Fifteenth Embodiment

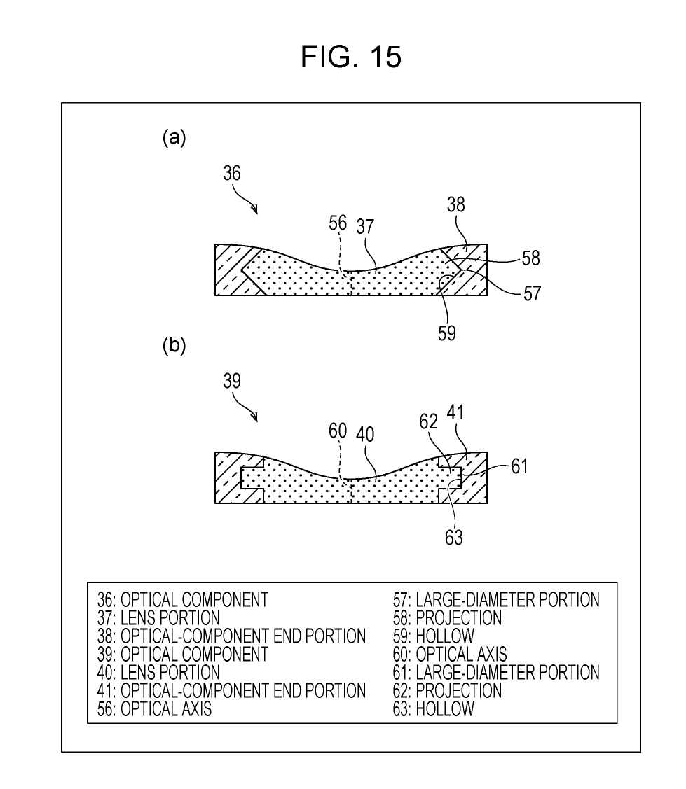

FIG. 15(a) is a sectional view illustrating a second modification of an optical component. FIG. 15(b) is a sectional view illustrating a third modification of an optical component. Each of an optical component 36 illustrated in FIG. 15(a) and an optical component 39 illustrated in FIG. 15(b) is usable as an alternative to each of the above-described optical components.

The optical component 36 includes a lens portion 37, which is a member corresponding to the lens portion 8 (refer to FIG. 2) in which the shape thereof is changed, and an optical-component end portion 38, which is a member corresponding to the optical-component end portion 9 (refer to FIG. 2) in which the shape thereof is changed. The lens portion 37 has a large-diameter portion 57 that has a cross-sectional area in a direction perpendicular to an optical axis 56 of the lens portion 37, the cross-sectional area being larger than the area of a surface of the lens portion 37 on the object side and being larger than the area of a surface of the lens portion 37 on the side of the sensor 2. The large-diameter portion 57 includes a leading end of a taper-shaped projection 58 that is formed on a side surface of the lens portion 37. A hollow 59 is formed in an inner wall of the optical-component end portion 38. The optical component 36 has a structure in which the projection 58 is fitted into the hollow 59.

According to the optical component 36, as a result of the projection 58 being fitted into the hollow 59, it is possible to prevent the lens portion 37 from coming off from the optical-component end portion 38.

The optical component 39 has a lens portion 40, which is a member corresponding to the lens portion 8 (refer to FIG. 2) in which the shape thereof is changed, and an optical-component end portion 41, which is a member corresponding to the optical-component end portion 9 (refer to FIG. 2) in which the shape thereof is changed. The lens portion 40 has a large-diameter portion 61 that has a cross-sectional area in a direction perpendicular to an optical axis 60 of the lens portion 40, the cross-sectional area being larger than the area of a surface of the lens portion 40 on the object side and being larger than the area of a surface of the lens portion 40 on the side of the sensor 2. The large-diameter portion 61 includes a leading end of a step-shaped projection 62 that is formed on a side surface of the lens portion 40. A hollow 63 is formed in an inner wall of the optical-component end portion 41. The optical component 39 has a structure in which the projection 62 is fitted into the hollow 63.

According to the optical component 39, as a result of the projection 62 being fitted into the hollow 63, it is possible to prevent the lens portion 40 from coming off from the optical-component end portion 41.

### Sixteenth Embodiment

A camera module that includes any of the optical apparatuses 101 to 112 (hereinafter referred to as a “first optical unit”) is also included in the category of the present invention.

In the aforementioned camera module, another optical unit (hereinafter referred to as a “second optical unit”) may be provided on the object side with respect to the first optical unit. The second optical unit may be an optical unit of a fixed-focus type or may be an optical unit that has an auto-focus function and/or a blur-correction function. An electrode for performing the auto-focus function and/or the blur-correction function of the second optical unit may be electrically connected to the first optical unit. The second optical unit may be disposed on a substrate (the substrate 1 or the like) so as to cover an optical component (the lens 3 or the like) of the first optical unit. A filter or the like that absorbs infrared rays may be inserted between the first optical unit and the second optical unit. Moreover, wiring (for example, a flexible printed board) for external connection may be electrically connected to the wiring (the wiring pattern 5 or the like) of the first optical unit.

### Overview

An optical apparatus according to a first aspect of the present invention includes a substrate in which an opening is formed, a light-receiving element (the sensor 2) that has a light-receiving portion and that is disposed in the opening, and an optical component (the lens 3 or the like) that is disposed on an object side with respect to the light-receiving element so as to close the opening and that guides light to the light-receiving portion. The optical component has a wiring pattern for electrically connecting the substrate and the light-receiving element to each other.

According to the aforementioned configuration, a projection that extends from an inner wall of the opening in a lateral direction is not required, which prevents the size of the opening from becoming smaller above the light-receiving element. Thus, the size of the opening at the light-receiving element and at a portion where the light-receiving element is disposed is not required to be increased. Consequently, it is possible to prevent an increase in the cross-sectional area of the substrate, a size increase in the light-receiving element, a decrease in design flexibility resulting from a decrease in the area of the front and rear surfaces of the substrate, an increase in the size (total optical length) of the optical apparatus in the vertical direction, and the like. Therefore, according to the aforementioned configuration, an LOC is enabled both to have a reduced size and to maintain high design flexibility.

An optical apparatus according to a second aspect of the present invention is the optical apparatus in the aspect 1 in which the optical component has a lens portion that functions as a lens that guides light to the light-receiving portion and; a lens-surrounding portion (the optical-component end portion 9 or the like), which is a hollow member disposed around the lens portion.

According to the aforementioned configuration, it is possible to prevent the optical characteristics of the optical component from being changed due to pressurizing and heating, by providing the lens-surrounding portion around the lens portion while employing as the lens-surrounding portion a member that has high resistance to a pressure and excellent heat resistance compared with the lens portion.

An optical apparatus according to a third aspect of the present invention is the optical apparatus in the second aspect in which the area of a surface of the lens portion on the object side is larger than the area of a surface of the lens portion on the side of the light-receiving element with the lens portion in plan view.

According to the aforementioned configuration, it is possible to achieve, for example, a funnel shape or a conical shape as the sectional shape of the optical component.

An optical apparatus according to a fourth aspect of the present invention is the optical apparatus in the second or third aspect in which a projection is formed on a side surface of the lens portion, and a step is formed on an inner wall of the lens-surrounding portion, the projection and the step being in contact with each other in a direction parallel to an optical axis of the lens portion.

According to the aforementioned configuration, it is possible to easily align the lens portion and the lens-surrounding portion with each other.

An optical apparatus according to a fifth aspect of the present invention is the optical apparatus in any of the second to fourth aspects in which the lens portion and the lens-surrounding portion are bonded to each other by an adhesive material (the adhesive 16).

An optical apparatus according to a sixth aspect of the present invention is the optical apparatus in the fourth aspect in which the lens portion and the lens-surrounding portion are bonded to each other by an adhesive material (the adhesive 20) at a portion that differs from a portion where the projection and the step are in contact with each other.

According to the aforementioned configuration, it is possible to create the optical component by bonding the lens portion and the lens-surrounding portion, which are members separated from each other, to each other with the adhesive material.

An optical apparatus according to a seventh aspect of the present invention is the optical apparatus in the fifth or sixth aspect in which the adhesive material has light-blocking properties.

According to the aforementioned configuration, it is possible to prevent, when the lens-surrounding portion is a light-transmissive member made of a glass or the like, flare or ghosting from being generated in an image obtained from the light-receiving element as a result of light being reflected inside the lens portion.

An optical apparatus according to an eighth aspect of the present invention is the optical apparatus in any of the fifth to seventh aspects in which the adhesive material has elasticity.

According to the aforementioned configuration, it is possible to prevent a malfunction from occurring in the optical apparatus as a result of the optical component being broken when a shock such as vibrations is applied to the optical apparatus. Specifically, it is possible to prevent bulk fracture of each member, interface fracture between the members, and the like in the optical component. In addition, according to the aforementioned configuration, it is possible to reduce a chance of occurrence of a partial blur as a result of the optical component inclining because it is possible to buffer stress that is generated along with expansion and contraction of each member.

An optical apparatus according to a ninth aspect of the present invention is the optical apparatus in the second aspect in which the lens-surrounding portion also functions as the substrate and extends in a direction parallel to an optical axis of the lens portion to at least a location next to the light-receiving element.

According to the aforementioned configuration, the optical apparatus has a structure commonly known as a cavity structure, in which at least surfaces, excluding a bottom surface, of the light-receiving element are surrounded by the optical component. The cavity structure enables the light-receiving element to be protected by the optical component.

An optical apparatus according to a tenth aspect of the present invention is the optical apparatus in any of the second to ninth aspects in which the lens portion has a large-diameter portion that has a cross-sectional area in a direction perpendicular to an optical axis of the lens portion, the cross-sectional area being larger than the area of a surface of the lens portion on the object side and being larger than the area of a surface of the lens portion on the side of the light-receiving element, the large-diameter portion including a leading end of a taper-shaped projection that is formed on a side surface of the lens portion.

An optical apparatus according to an eleventh aspect of the present invention is the optical apparatus in any of the second to ninth aspects in which the lens portion has a large-diameter portion that has a cross-sectional area in a direction perpendicular to an optical axis of the lens portion, the cross-sectional area being larger than the area of a surface of the lens portion on the object side and being larger than the area of a surface of the lens portion on the side of the light-receiving element, the large-diameter portion including a leading end of a step-shaped projection that is formed on a side surface of the lens portion.

According to the aforementioned configuration, when a hollow is formed in the inner wall of the lens-surrounding portion, it is possible, as a result of the projection being fitted into the hollow, to prevent the lens portion from coming off from the lens-surrounding portion.

An optical apparatus according to a twelfth aspect of the present invention is the optical apparatus in any of the first to eleventh aspects in which the optical component includes a first optical region that includes a surface of the optical component on the object side and that is made of a plastic and a second optical region that includes a surface of the optical component on the side of the light-receiving element and that is made of a glass or a plastic.

Typically, lenses that are represented by lenses for LOC use have a thickness deviation that increases as the performance of the lenses increases, and the thickness of the lenses is thus required to be reduced, which increases the degree of difficulty in molding. In particular, the degree of difficulty in molding a glass lens is remarkably high compared with that of a plastic lens. According to the aforementioned configuration, the optical component has the second optical region in addition to the first optical region, and it is thus possible to form the optical component so as to have a large thickness deviation and so as to be thin. In addition, according to the aforementioned configuration, the optical component has the second optical region that is made of a glass and thus has high resistance to a load and has excellent heat resistance.

An optical apparatus according to a thirteenth aspect of the present invention is the optical apparatus in the twelfth aspect in which the second optical region extends to a location next to the first optical region.

According to the aforementioned configuration, it is possible to achieve a configuration in which the first optical region is protected by the second optical region.

An optical apparatus according to a fourteenth aspect of the present invention is the optical apparatus in the first aspect in which a clearance between the substrate and the optical component may be greater than or equal to a clearance between the light-receiving element and the optical component.

An optical apparatus according to a fifteenth aspect of the present invention is the optical apparatus in any of the first to fourteenth aspects in which a groove or a slit is formed in at least one of a surface of the optical component on the object side and a surface of the optical component on the side of the light-receiving element.

According to the aforementioned configuration, it is possible to prevent a malfunction from occurring in the optical apparatus as a result of the optical component being broken when a shock such as vibrations is applied to the optical apparatus. In addition, it is possible to reduce a chance of occurrence of a partial blur as a result of the optical component inclining because it is possible to buffer stress that is generated along with expansion and contraction of each member.

An optical apparatus according to a sixteenth aspect of the present invention is the optical apparatus in any of the first to fifteenth aspects in which the optical component has a body that functions as a lens that guides light to the light-receiving portion, a frame that supports the body, and a suspended portion that is suspended between the body and the frame.

According to the aforementioned configuration, it is possible to achieve a size reduction and high performance in the optical apparatus while suppressing an optically effective region from decreasing.

An optical apparatus according to a seventeenth aspect of the present invention is the optical apparatus in any of the first to sixteenth aspects in which the wiring pattern may be constituted by a molded interconnect device.

An optical apparatus according to an eighteenth aspect of the present invention is the optical apparatus in any of the first to seventeenth aspects in which the wiring pattern is formed on a surface of a coating provided on a surface of the optical component.

According to the aforementioned configuration, it is possible to prevent flare or ghosting from being generated in an image obtained from the light receiving element as a result of light being reflected inside the optical component because the surface of the coating has light-blocking properties.

A camera module according to a nineteenth aspect of the present invention, the camera module including the optical apparatus according to any of the first to eighteenth aspects, is also included in the category of the aspects of the present invention.

The present invention is not limited to the embodiments described above and can be variously modified within the scope indicated in the claims. The technical scope of the present invention includes embodiments that are obtained by combining, as appropriate, the technical means disclosed in different embodiments. Further, a technical feature can be newly formed by combining the technical means disclosed in different embodiments.

### REFERENCE SIGNS LIST

1, 34 substrate
2 sensor (light-receiving element)
3 lens (optical component)
4, 24, 35 opening
5, 27 wiring pattern
6, 55 bump
7, 10, 13, 17, 21, 28, 31, 36, 39, 64, 67, 73, 76 optical component
8, 11, 14, 18, 22, 37, 40, 65, 68 lens portion
9, 12, 15, 19, 23, 38, 41 optical-component end portion (lens-surrounding portion)
16, 20 adhesive (adhesive material)
29, 32 first optical region
30, 33 second optical region
42 light-receiving portion
43, 45, 48, 51, 52, 56, 60 optical axis
44 center of light-receiving portion
46, 49, 70 projection
47, 50 step
53 bottom portion
54 adhesive
57, 61 large-diameter portion
58, 62 projection
59, 63 hollow
66, 69, 74 groove
71 inner side of projection
72 outer side of projection
75 slit
77 body
78 frame
79 suspended portion
101 to 112 optical apparatus

1. An optical apparatus comprising:
a substrate in which an opening is formed;
a light-receiving element that has a light-receiving portion and that is disposed in the opening; and
an optical component that is disposed on an object side with respect to the light-receiving element so as to close the opening and that guides light to the light-receiving portion,
wherein the optical component has a wiring pattern for electrically connecting the substrate and the light-receiving element to each other,
wherein the optical component has a lens portion that functions as a lens that guides light to the light-receiving portion; and a lens-surrounding portion, which is a hollow member disposed around the lend portion, and
wherein the wiring pattern is formed on a surface of the lens-surrounding portion, the surface being parallel to and flush with a surface of the lens portion on a side of the light-receiving element.

2. (canceled)

3. The optical apparatus according to claim 21, wherein with the lens portion in plan view,
an area of a surface of the lens portion on the object side is larger than an area of a surface of the lens portion on the side of the light-receiving element.

4. The optical apparatus according to claim 1,
wherein a projection is formed on a side surface of the lens portion,
wherein a step is formed on an inner wall of the lens-surrounding portion, and
wherein the projection and the step are in contact with each other in a direction parallel to an optical axis of the lens portion.

5. The optical apparatus according to claim 1, wherein the lens portion and the lens-surrounding portion are bonded to each other by an adhesive material.

6. The optical apparatus according to claim 4, wherein the lens portion and the lens-surrounding portion are bonded to each other by the adhesive material at a portion that differs from a portion where the projection and the step are in contact with each other.

7. The optical apparatus according to claim 5, wherein the adhesive material has light-blocking properties.

8. The optical apparatus according to claim 5, wherein the adhesive material has elasticity.

9. The optical apparatus according to claim 1,
wherein the lens-surrounding portion also functions as the substrate, and
wherein the lens-surrounding portion extends in a direction parallel to an optical axis of the lens portion to at least a location next to the light-receiving element.

10. The optical apparatus according to claim 1,
wherein the lens portion has a large-diameter portion that has a cross-sectional area in a direction perpendicular to an optical axis of the lens portion, the cross-sectional area being larger than an area of a surface of the lens portion on the object side and being larger than an area of a surface of the lens portion on the side of the light-receiving element, and
wherein the large-diameter portion includes a leading end of a taper-shaped projection that is formed on a side surface of the lens portion.

11. The optical apparatus according to claim 1,
wherein the lens portion has a large-diameter portion that has a cross-sectional area in a direction perpendicular to an optical axis of the lens portion, the cross-sectional area being larger than an area of a surface of the lens portion on the object side and being larger than an area of a surface of the lens portion on the side of the light-receiving element, and
wherein the large-diameter portion includes a leading end of a step-shaped projection that is formed on a side surface of the lens portion.

12. The optical apparatus according to claim 1, wherein the optical component has
a first optical region that includes a surface of the optical component on the object side and that is made of a plastic, and
a second optical region that includes a surface of the optical component on the side of the light-receiving element and that is made of a glass or a plastic.

13. The optical apparatus according to claim 12, wherein the second optical region extends to a location next to the first optical region.

14. The optical apparatus according to claim 1, wherein a clearance between the substrate and the optical component is greater than or equal to a clearance between the light-receiving element and the optical component.

15. The optical apparatus according to claim 1, wherein a groove or a slit is formed in at least one of a surface of the optical component on the object side and a surface of the optical component on the side of the light-receiving element.

16. The optical apparatus according to claim 1, wherein the optical component has
a body that functions as a lens that guides light to the light-receiving portion,
a frame that supports the body, and
a suspended portion that is suspended between the body and the frame.

17. The optical apparatus according to claim 1, wherein the wiring pattern is constituted by a molded interconnect device.

18. The optical apparatus according to claim 1, wherein the wiring pattern is formed on a surface of a coating that is provided on a surface of the optical component.

19. A camera module comprising the optical apparatus according to claim 1.

20. The optical apparatus according to claim 1, wherein the lens portion and the lens-surrounding portion are integral with each other.

21. An optical apparatus comprising:
a substrate in which an opening is formed;
a light-receiving element that has a light-receiving portion and that is disposed in the opening; and
a lens that is disposed on an object side with respect to the light-receiving element so as to close the opening and that guides light to the light-receiving portion,
wherein the lens has a wiring pattern for electrically connecting the substrate and the light-receiving element to each other.
